(19) United States
(12) Patent Application Publication
(10) Pub. No.: US 2025/0309625 A1
(43) Pub. Date: Oct. 2, 2025

(54) MULTILAYER, EMI SHIELDING, SELF-WRAPPING TEXTILE SLEEVE AND METHOD OF CONSTRUCTION THEREOF

(71) Applicant: FEDERAL-MOGUL POWERTRAIN LLC, Northville, MI (US)

(72) Inventor: Xavier Lernon, Northville, MI (US)

(21) Appl. No.: 18/625,197

(22) Filed: Apr. 2, 2024

(51) Int. Cl. H02G 3/04; D03D 1/00; D03D 3/02; H05K 9/00

(52) U.S. Cl. CPC H02G 3/0481; D03D 1/0043; D03D 1/0058; D03D 3/02; H05K 9/009; H05K 9/0098; D10B 2401/04; D10B 2401/16

(57) ABSTRACT

An electromagnetic interference shielding, self-wrapping textile sleeve for providing EMI protection about an elongate member includes an outer wall of interlaced wire to provide protection low frequency EMI frequency as low or lower than 100 MHz. The outer wall has opposite outer edges extending lengthwise between opposite outer ends. The sleeve includes an inner wall of interlaced yarns fixed to the outer wall to provide protection against EMI frequency as high as or higher than 1 GHz. The inner wall has opposite inner edges extending lengthwise between opposite inner ends. The interlaced yarns include heat-set yarn that impart a bias to cause the inner and outer edges to self-wrap into overlapping relation with one another and yarn having an outermost layer of conductive material bonded thereto.

### BACKGROUND OF THE INVENTION

### 1. Technical Field

This invention relates generally to tubular protective sleeves for providing protection to an elongate member contained therein, and more particularly to textile tubular protective sleeves for providing protection to an electrical member against electromagnetic interference and to their method of construction.

### 2. Related Art

It is known to contain and protect elongate members, such as wires and wire harnesses, for example, in wrappable textile sleeves to provide protection to cables, wires, and hoses contained therein. Improvements of known wrappable textile sleeves are desired to provide enhanced protection, including protection against electromagnetic interference over a broad frequency range, such as ranging between about 100 MHz and 1 GHz, while also being flexible for routing cables, wires and wire harnesses through winding areas, while also having a low, non-bulky radially extending profile for applications having tight passages and weight restrictions, such as in automotive, aircraft and aerospace applications, for example, while also being economical in manufacture.

### SUMMARY OF THE INVENTION

In accordance with one aspect of the invention, an electromagnetic interference (EMI) shielding, self-wrappable textile sleeve for providing EMI protection about an elongate member is provided. The sleeve includes an outer wall of interlaced wire to provide protection against a low frequency EMI range, including as low or lower than 100 MHz. The outer wall has opposite outer edges extending lengthwise between opposite outer ends. The sleeve also includes an inner wall of interlaced yarns fixed to the outer wall to provide protection against a high frequency EMI range, including as high or higher than 1 GHz. The inner wall has opposite inner edges extending lengthwise between opposite inner ends. The interlaced yarns include heat-set yarn that impart a bias to cause the inner and outer edges to self-wrap into overlapping relation with one another. The interlaced yarns also include yarn having an outermost layer of conductive material bonded thereto. The synergies provided by the outer and inner walls thereby provides a wide range of protection against EMI, including a continuous range as low or lower than 100 MHz and as high or higher than 1 GHz.

In accordance with another aspect of the invention, the wherein the outer wall is fixed to the inner wall by a stitching extending between the opposite outer and inner ends, the stitching extending adjacent the opposite outer and inner edges.

In accordance with another aspect of the invention, the outer wall and the inner wall are detached from one another between the stitching.

In accordance with another aspect of the invention, the heat-set yarn includes the conductive material bonded thereto.

In accordance with another aspect of the invention, the conductive material is a conductive metalized coating.

In accordance with another aspect of the invention, the conductive metalized is selected from one of nickel, copper, silver, or aluminum.

In accordance with another aspect of the invention, the interlaced wire shields low frequency EMI as low as 100 MHz, and the yarn having an outermost layer of conductive material bonded thereto shields high frequency EMI as high as 1 GHz.

In accordance with another aspect of the invention, the interlaced wire is woven.

In accordance with another aspect of the invention, the interlaced wire is braided.

In accordance with another aspect of the invention, the interlaced yarn is woven.

In accordance with another aspect of the invention, the interlaced yarn is braided.

In accordance with another aspect of the invention, the interlaced wire is provided, at least in part, as bundles of wire.

In accordance with another aspect of the invention, a method of constructing an electromagnetic interference shielding, self-wrappable textile sleeve for providing EMI protection about an elongate member is provided. The method includes interlacing wire to form an outer wall having opposite outer edges extending lengthwise between opposite outer ends. Further, interlacing yarns to form an inner wall having opposite inner edges extending lengthwise between opposite inner ends and fixing the inner wall to the outer wall. Then, biasing said inner and outer edges of the inner and outer walls into overlapping relation with one another by heat-setting at least some of the interlaced yarns. Further yet, providing at least some of the interlaced yarns having an outermost layer of conductive material bonded thereto.

In accordance with another aspect of the invention, the method can further include fixing the outer wall to the inner wall by a stitching extending between the opposite outer and inner ends adjacent the opposite outer and inner edges.

In accordance with another aspect of the invention, the method can further include leaving the outer wall and the inner wall detached from one another between the stitching.

In accordance with another aspect of the invention, the method can further include providing the heat-set yarn including the conductive material bonded thereto.

In accordance with another aspect of the invention, the method can further include interlacing the wire to shield low frequency EMI as low as 100 MHz, and bonding the outermost layer of conductive material to the interlaced yarns to shield high frequency EMI as high as 1 GHz.

In accordance with another aspect of the invention, the method can further include interlacing the wire in a braiding process.

In accordance with another aspect of the invention, the method can further include interlacing the yarns in a weaving process.

In accordance with another aspect of the invention, the method can further include interlacing the wire in a weaving process.

### BRIEF DESCRIPTION OF THE DRAWINGS

These and other aspects, features and advantages of the present invention will become more readily appreciated when considered in connection with the following detailed description of presently preferred embodiments and best mode, appended claims and accompanying drawings, in which:

FIG. 1 is a schematic isometric view of an electromagnetic shielding, self-wrapping textile tubular sleeve constructed in accordance with one aspect of the invention shown with an elongate electrical member to be protected extending through a central cavity bounded a multilayer wall of the sleeve;

FIG. 2 is a schematic cross-sectional view of the sleeve taken generally along the line 2-2 of FIG. 1;

FIG. 3A is a schematic plan view of the sleeve of FIG. 1 shown in a pre-finished state prior to being heat-set into a self-wrapping finished state, with a radially outwardly facing outer surface of the sleeve shown;

FIG. 3B is a view similar to FIG. 3A with a radially inwardly facing inner surface of the sleeve shown;

FIG. 3C is an end view looking generally in the direction of arrow 3A of FIG. 3A;

FIG. 4A is a cross-sectional view illustrating one aspect of a yarn of the inner wall;

FIG. 4B is a cross-sectional view illustrating another aspect of a yarn of the inner wall; and

FIG. 4C is a cross-sectional view illustrating one aspect of a mini-braid of wire of the outer wall.

### DETAILED DESCRIPTION OF PRESENTLY PREFERRED EMBODIMENTS

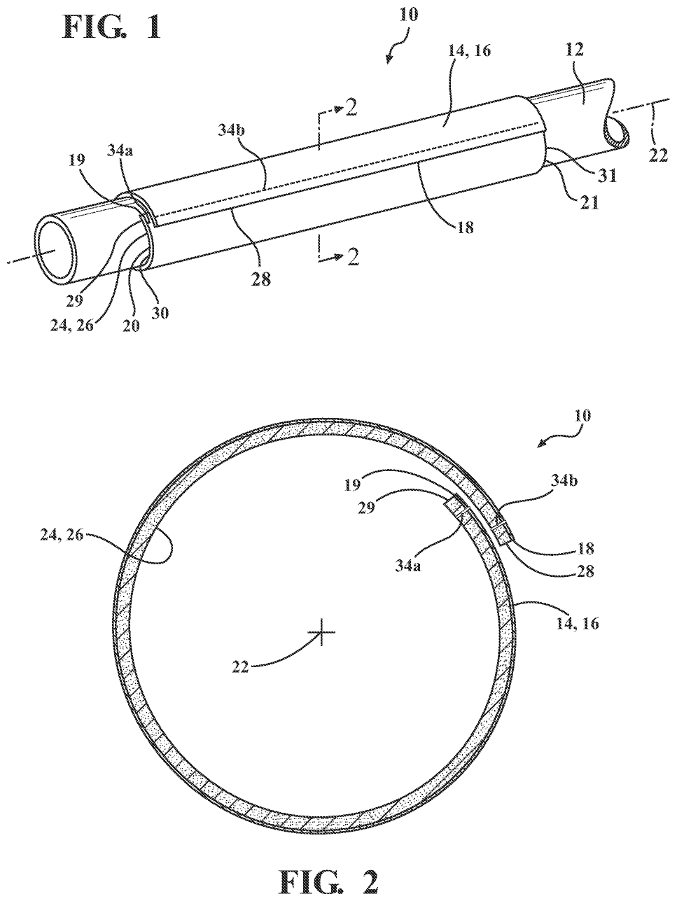

Referring in more detail to the drawings, FIGS. 1 and 2 illustrate an electromagnetic interference shielding, self-wrappable textile sleeve, referred to hereafter as sleeve 10, for providing EMI protection about an elongate member 12, such as a wire, wire harness, or other electricity conveying member. The sleeve 10 includes an outer wall 14 of interlaced wires 16. The outer wall 14 has opposite outer edges 18, 19 extending lengthwise between opposite outer ends 20, 21. The opposite edges 18, 19 are shown as extending generally parallel to a central longitudinal axis 22. The sleeve 10 further includes an inner wall 24 of interlaced yarns 26. The interlaced yarns 26 are fixed against separation to the outer wall 14. The inner wall 24 has opposite inner edges 28, 29 extending lengthwise between opposite inner ends 30, 31. The interlaced yarns 26 include heat-set yarn(s) 25 configured to bias the inner edges 28, 29 and outer edges 18, 19 into overlapping relation with one another. The interlaced yarns 26 further include conductive yarn 27 having an outermost layer 32 of conductive material bonded thereto. The outer wall 14 and interlaced wire 16 thereof shield low frequency EMI as low as 100 MHZ, and the inner wall 24 and interlaced yarn 26 thereof shield high frequency EMI as high as 1 GHz. Accordingly, the elongate member 12 is thoroughly shielded against EMI over a wide range of frequencies.

The outer wall 14 is fixed to the inner wall 24 by a stitching extending between the opposite outer ends 20, 21 and inner ends 30, 31. The stitching extends from one of the outer and inner ends 20, 30 to the opposite outer and inner ends 21, 31 adjacent the opposite outer edges 18, 19 and inner edges 28, 29. The stitching is thusly provided as a pair of stitches 34a, 34b extending in generally parallel relation with one another in generally parallel relation with the central longitudinal axis 22. The stitches 34a, 34b are the sole connection of the outer wall 14 to the inner wall 24, and thus, the outer and inner walls 14, 24 are entirely detached from one another between the stitches 34a, 34b, such that the outer and inner walls 14, 24 are free to move and shift relative to another between the stitches 34a, 34b, thereby enhancing flexibility and EMI performance of the sleeve 10. The stitching 34 can be provided with a conductive wire, conductive yarn, or otherwise can be provided with a high strength yarn, including a non-conductive monofilament or multifilament.

The heat-set yarn 25 of the inner wall 24 can be provided as any suitable heat-set monofilament material or multifilament material, such as polypropylene, polyethylene, or otherwise. The heat-set yarn 25 can be coated with the outermost layer of conductive material 32 bonded thereto, such that the heat-set yarn 25 forms an inner core, and the conductive material 32 forms an outer layer encasing the inner core (FIG. 4A). The heat-set yarn 25 extends circumferentially about the central longitudinal axis 22, and thus, the heat-set imparts a bias on the inner wall 24, which in turns imparts a bias on the outer wall 14, thereby causing the opposite outer edges 18, 19 and the opposite inner edges 28, 29 to be biased into circumferentially overlapped relation with one another. As such, circumferentially continuous EMI protection is automatically provided to the elongate member 12 by the self-wrapped outer and inner walls 14, 24. The conductive material 32 can be provided as a metallized coating, such as from nickel, copper, silver, aluminum or any alloy thereof, such as NiCu, by way of example and without limitation.

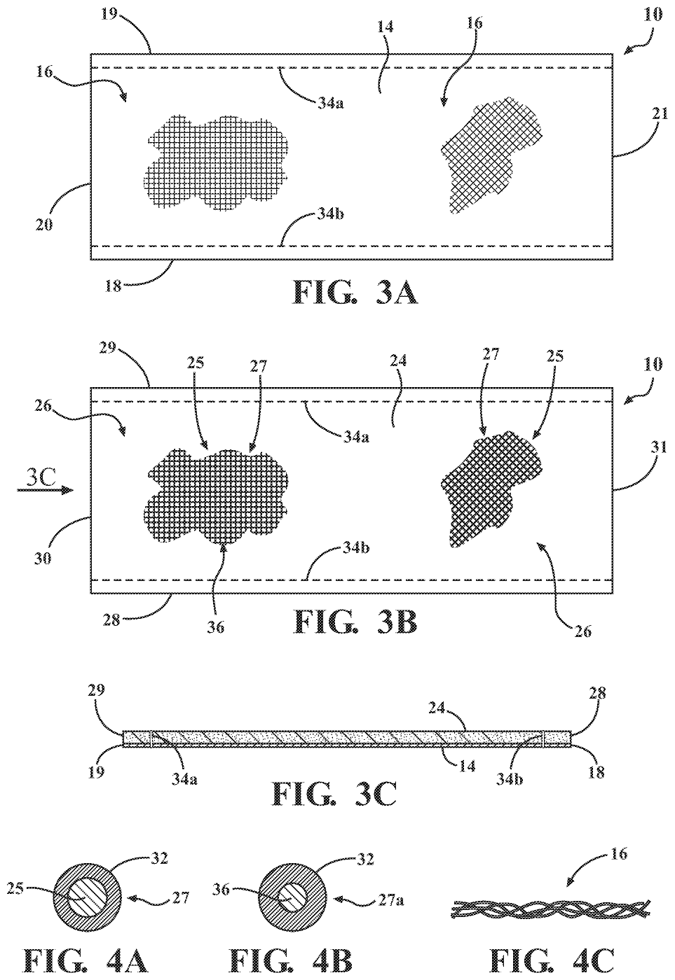

The outer and inner walls 14, 24 can be woven or braided, with a woven embodiment schematically depicted on the left portion of FIGS. 3A and 3B, and a braided embodiment schematically depicted on the right portion of FIGS. 3A and 3B. As such, it is to be recognized that the outer wall 14 can be woven and the inner wall 24 can be woven or braided. Conversely, the outer wall 14 can be braided and the inner wall 24 can be woven or braided. If one of the walls 14, 24 is woven and the other braided, enhanced EMI protection may be achieved due to a crossing of yarns of the outer and inner wall 14, 24 in oblique relation with one another. If the inner wall 24 is woven, weft yarns can extend circumferentially in generally transverse relation with the central longitudinal axis 22 and warp yarns can extend lengthwise in generally parallel relation with the central longitudinal axis 22. At least some or all of the weft yarns can be provided as conductive yarns 27, with at least some or all of the conductive weft yarns 27 having a heat-set yarn core having the conductive material 32 coated thereon, while the lengthwise extending conductive warp yarn 27a (FIG. 4B) can be provided as a less costly, non-heat-settable yarn 36 having the conductive material 32 coated thereon. Otherwise, if the inner wall 24 is braided, at least some or all the yarns can be provided as heat-set yarn having the conductive material 32 coated thereon. The conductive material 32 of the inner wall 24 provides EMI protection up to and beyond a frequency of 1 GHz.

The electrically conductive wire 16 of the outer wall 14 can be provided having a diameter between about 0.05-0.2 mm, and in one non-limiting embodiment, a diameter between 0.8-1.2 mm, by way of example and without limitation, to provide resistance to low frequency EMI, such as less than 100 MHz. To maximize protection against low frequency EMI, the conductive wire 16 is provided as individual continuous wire filaments, wherein at least some of the wire filaments 16 can be bundled wire filaments, including in side-by-side relation with one another, such that the individual wires 16 in each bundle extend parallel with one another, or the wires 16 can be provided as mini-braids of continuous wire filaments (FIG. 4C), with mini-braid multifilaments being well understood by a person possessing ordinary skill in the art. The wire 16 can be provided as copper wire, silver wire, steel wire, any of the aforementioned as a core encapsulated by an outer layer of tin, nickel, or silver by way of example and without limitation.

In accordance with another aspect of the invention, a method of constructing an electromagnetic interference shielding, self-wrappable textile sleeve 10 for providing EMI protection about an elongate member 12 is provided. The method includes interlacing wire 16 to form an outer wall 14 having opposite outer edges 18, 19 extending lengthwise between opposite outer ends 20, 21. Further, interlacing yarns 26 to form an inner wall 24 having opposite inner edges 28, 29 extending lengthwise between opposite inner ends 30, 31 and fixing the inner wall 24 to the outer wall 14. Then, biasing said inner and outer edges of the inner and outer walls 24, 14 into overlapping relation with one another by heat-setting at least some of the interlaced yarns 26. Further yet, providing at least some of the interlaced yarns 26 having an outermost layer of conductive material 32 bonded thereto.

In accordance with another aspect of the invention, the method can further include fixing the outer wall 14 to the inner wall 24 by a stitching 34a, 34b extending between the opposite outer and inner ends 20, 21, 30, 31 adjacent the opposite outer and inner edges 18, 19, 28, 29.

In accordance with another aspect of the invention, the method can further include leaving the outer wall 14 and the inner wall 24 entirely detached from one another between the stitching 34a, 34b.

In accordance with another aspect of the invention, the method can further include providing the heat-set yarn 25 including the conductive material 32 bonded thereto.

In accordance with another aspect of the invention, the method can further include interlacing the wire 16 to shield low frequency EMI as low as 100 MHz, and bonding the outermost layer of conductive material 32 to the interlaced yarns 26 to shield high frequency EMI as high as 1 GHz.

In accordance with another aspect of the invention, the method can further include interlacing the wire 16 in a braiding process.

In accordance with another aspect of the invention, the method can further include interlacing the yarns 26 in a weaving process.

In accordance with another aspect of the invention, the method can further include interlacing the wire 16 in a weaving process.

Many modifications and variations of the present invention are possible in light of the above teachings, as will be readily appreciated by one possessing ordinary skill in the art. It is contemplated that all features of all claims and of all embodiments can be combined with each other, so long as such combinations would not contradict one another. It is, therefore, to be understood that the invention may be practiced otherwise than as specifically described, and that the scope of the invention is defined by any ultimately allowed claims.

1. An electromagnetic interference shielding, self-wrappable textile sleeve for providing EMI protection about an elongate member, comprising:
an outer wall of interlaced wire, said outer wall having opposite outer edges extending lengthwise between opposite outer ends;
an inner wall of interlaced yarns fixed to the outer wall, said inner wall having opposite inner edges extending lengthwise between opposite inner ends, said interlaced yarns including heat-set yarn biasing said inner and outer edges into overlapping relation with one another and yarn having an outermost layer of conductive material bonded thereto.

2. The electromagnetic interference shielding, self-wrappable textile sleeve of claim 1, wherein the outer wall is fixed to the inner wall by a stitching extending between the opposite outer and inner ends, the stitching extending adjacent the opposite outer and inner edges.

3. The electromagnetic interference shielding, self-wrappable textile sleeve of claim 2, wherein the outer wall and the inner wall are detached from one another between the stitching.

4. The electromagnetic interference shielding, self-wrappable textile sleeve of claim 1, wherein the heat-set yarn includes the conductive material bonded thereto.

5. The electromagnetic interference shielding, self-wrappable textile sleeve of claim 4, wherein the conductive material is a conductive metalized coating.

6. The electromagnetic interference shielding, self-wrappable textile sleeve of claim 5, wherein the conductive metalized is selected from one of nickel, copper, silver, or aluminum.

7. The electromagnetic interference shielding, self-wrappable textile sleeve of claim 1, wherein the interlaced wire shields low frequency EMI as low as 100 MHz, and the yarn having an outermost layer of conductive material bonded thereto shields high frequency EMI as high as 1 GHz.

8. The electromagnetic interference shielding, self-wrappable textile sleeve of claim 1, wherein the interlaced wire is woven.

9. The electromagnetic interference shielding, self-wrappable textile sleeve of claim 1, wherein the interlaced wire is braided.

10. The electromagnetic interference shielding, self-wrappable textile sleeve of claim 1, wherein the interlaced yarn is woven.

11. The electromagnetic interference shielding, self-wrappable textile sleeve of claim 1, wherein the interlaced yarn is braided.

12. The electromagnetic interference shielding, self-wrappable textile sleeve of claim 1, wherein the interlaced wire is provided, at least in part, as bundles of wire.

13. A method of constructing an electromagnetic interference shielding, self-wrappable textile sleeve for providing EMI protection about an elongate member, comprising:
interlacing wire to form an outer wall having opposite outer edges extending lengthwise between opposite outer ends;
interlacing yarns in fixed relation to the outer wall, with the inner wall having opposite inner edges extending lengthwise between opposite inner ends;
biasing said inner and outer edges of the inner and outer walls into overlapping relation with one another by heat-setting at least some of the interlaced yarns; and
providing at least some of the interlaced yarns having an outermost layer of conductive material bonded thereto.

14. The method of claim 13, further including fixing the outer wall to the inner wall by a stitching extending between the opposite outer and inner ends adjacent the opposite outer and inner edges.

15. The method of claim 14, further including leaving the outer wall and the inner wall detached from one another between the stitching.

16. The method of claim 13, further including providing the heat-set yarn including the conductive material bonded thereto.

17. The method of claim 13, further including interlacing the wire to shield low frequency EMI as low as 100 MHz, and bonding the outermost layer of conductive material to the interlaced yarns to shield high frequency EMI as high as 1 GHz.

18. The method of claim 13, further including interlacing the wire in a braiding process.

19. The method of claim 18, further including interlacing the yarns in a weaving process.

20. The method of claim 13, further including interlacing the wire in a weaving process.
